(19) United States
(12) Patent Application Publication
(10) Pub. No.: US 2026/0068542 A1
(43) Pub. Date: Mar. 5, 2026

(54) Stack Structure For Retention of High and Low Resistive States of an Oxide-Based Random-Access Memory

(71) Applicant: WEEBIT NANO LTD, Hod Hasharon (IL)

(72) Inventor: Gabriel Molas, Fontanil Cornillon (FR)

(73) Assignee: WEEBIT NANO LTD, Hod Hasharon (IL)

(21) Appl. No.: 19/314,270

(22) Filed: Aug. 29, 2025

(30) Foreign Application Priority Data
Sep. 2, 2024 (FR) FR2409335

(51) Int. Cl. H10N 70/20; H10B 63/00; H10N 70/00

(52) U.S. Cl. CPC H10N 70/24; H10B 63/00; H10N 70/8833

(57) ABSTRACT

A resistive stack (Stck) for a resistive random-access memory cell, the resistive stack comprising: a first electrode (E11); a second electrode (E12); a dielectric layer (Diel) interposed between the first electrode (E11) and the second electrode (E12), the dielectric layer comprising: a first dielectric layer (Diel1) formed from a first transition metal oxide; a second dielectric layer (Diel2) formed from a second transition metal oxide different from the first transition metal oxide; and a diffusion barrier layer (DiffBar) interposed between the first dielectric layer (Diel1) and the second dielectric layer (Diel2), and formed from a material having a barrier property with regard to oxygen vacancies, that is higher than barrier properties with regard to oxygen vacancies of the first transition metal oxide and the second transition metal oxide.

### CROSS-REFERENCE TO RELATED APPLICATION

The present application claims priority to French Patent Application No. FR2409335 filed on Sep. 2, 2024, the contents of which are hereby incorporated by reference in their entirety.

### FIELD OF THE INVENTION

The technical domain of the invention is that of Resistive Random Access Memory (ReRAM) or Resistive RAM, that each comprise an element whose resistive state defines a bit of information. More specifically, the invention concerns the structure of the stack of materials forming the active portion of an oxide-based ReRAM also called OxRAM.

### BACKGROUND OF THE INVENTION

Non-volatile memory (NVM) is a kind of computer memory able to retain information even when its power source is turned off. Examples of non-volatile memories include read-only memories (ROM), erasable ROM (EPROM), flash memories, ferroelectric random-access memories (FRAM), magnetoresistive random access memories (MRAM), phase-change memories (PCM) and resistive random access memories (ReRAM).

The latter type of memories, the ReRAM, is typically formed by an array of stacks Stck of a layer Diel made of a dielectric solid-state material and two electrodes El1 and El2 between which the layer Diel is interposed, as illustrated by FIG. 1. Such a structure constitutes a memory bit element and works typically by changing the electrical resistance of the layer Diel. The dielectric solid-state material may be for example a chalcogenide, a perovskite or an oxide of a transition metal such as hafnium oxide (HfOx). A memory is formed of an array of such memory bit elements each forming the core of one bit cell. The present application focus on a ReRAM employing oxides of transition metals to form the dielectric solid-state material, i.e. to form an OxRAM.

FIG. 1 illustrates the functioning of an OxRAM memory element that is made of stack Stck comprising a pair of electrode El1 and El2 between which a dielectric active layer Diel is interposed.

During a set operation Set, application of a set electrical current and a set voltage Vₛₑₜ along with an associated electrical field in a first direction between the two electrodes El1 and El2 can lead to the formation of an electrically conductive filament Fil in the otherwise electrically resistive layer Diel, due to the formation and diffusion of pairs of oxygen ions Oxy and oxygen vacancies V_{Oxy} in the volume of the dielectric layer Diel. The bit element is then put in a low resistance state or LRS. The higher the set current, the larger the filament and the lower the resistance of the bit element.

Conversely, during a reset operation Reset, a reset electrical current running between the two electrodes El1 and El2 in a second direction, opposite to the first direction, and similarly application a voltage Vᵣₑₛₑₜ opposite to Vₛₑₜ between the two electrodes, can dissolve the electrically conductive filament Fil created during the set operation Set, thus increasing the electrical resistance of the bit element. The bit element is then put in a high resistance state or HRS.

Each of the LRS and HRS states can be associated to a bit value of a digital memory. During a read operation, a read voltage V_{read} is applied between the electrodes and a read current is measured. The read current is lower in intensity than both the set current and the reset current, and runs between the two electrodes. Measuring the read current allows to evaluate the resistive state of the bit element, and thus the associated bit value.

Here, electrode El1 is inert, to the extent that it does not play an active role in the structure, but passively carry electrons. On the other hand, electrode El2 is active, acting as an oxygen reservoir that can scavenge oxygen ions from the dielectric layer during set operations and release oxygen ions to the dielectric layer during reset operations.

The formation and dissolution processes of the filament and its final configuration, which determines the resistance of the memory element in the LRS are stochastic in nature. Otherwise stated, the characteristics of the bit cells spread over ranges. In this context, FIG. 2 illustrates the resistances of a collection of bit cells of a same array.

FIG. 2(A) and (B) illustrates the probability Pr for each of the bit cells of an array to take a given resistance value R(Ω), in an ideal case and in a more realistic case, respectively. In the ideal case, only two values are possible: a unique first value for the resistance of the Low Resistance State LRS and a second unique value for the resistance of the High Resistance State HRS.

In the ideal model, only these two states are accessible to the bit cells, and each one has a unique, well defined, resistance value. However, in practice, the resistance values spread over ranges that can each be described as a probability density having the shape of a peak centered on a given value (R_{0_LRS} and R_{0_HRS} for the two states LRS and HRS, respectively) and presenting a standard deviation σ (similar repartitions for LRS and HRS in this example, for the sake of keeping the explanation simple), as illustrated by FIG. 2(B).

As illustrated by FIG. 2(B), the two states LRS and HRS can in fact be close to one another. The distributions of these two states can even overlap, which makes the control of the state of the memory cell more complicated. In particular, a retention problem of the information in a memory occurs: over time, the state (LRS or HRS) of any given bit element may progressively drift apart from the one that has been written (set or reset) initially, and may become difficult to be determined during a read operation: does the measured resistance value corresponds to a LRS state or a HRS state?

Retention issues are known to relate to the migrations of oxygen ions and oxygen vacancies within the dielectric layer, as well as to the release of the scavenged oxygen ions from the active electrode to the dielectric layer. Indeed, the state of a bit element is determined by the presence of oxygen vacancies in the dielectric layer, and their positioning: do they form or not a conductive filament? However, migration of oxygen vacancies V_{Oxy} can dissolve a filament formed by a set operation, thus creating a problem of retention of the low resistive state. Conversely, migration of oxygen ions Oxy can reconstruct a filament dissolved by a reset operation, thus creating a problem of retention of the high resistive state. Oxygen ions can originate from the electrode El1. These phenomena are exacerbated by the temperature.

Thus, there is a need of improving the retention characteristics of OxRAM memories, especially when high temperature applications are targeted.

### OBJECT OF THE INVENTION

In the context described above, the inventors propose a structure of a memory element able to limit the occurrence of unwanted filament reformation, and that thus provides better retention characteristics to a memory based on such memory element, in particular the HRS retention.

### SUMMARY OF THE INVENTION

To this effect, a first aspect of the invention relates to a resistive stack for a resistive random-access memory cell, the resistive stack comprising: a first electrode; a second electrode; a dielectric layer interposed between the first electrode and the second electrode, the dielectric layer comprising: a first dielectric layer formed from a first transition metal oxide formed from a first transition metal; a second dielectric layer formed from a second transition metal oxide formed from a second transition metal, the first transition metal being different from the second transition metal; and a diffusion barrier layer interposed between the first dielectric layer and the second dielectric layer, and formed from a material having a barrier property with regard to oxygen vacancies, that is higher than barrier properties with regard to oxygen vacancies of the first transition metal oxide and the second transition metal oxide, the diffusion barrier layer being formed from aluminum oxide, SiO2 or Si.

The diffusion barrier interposed between the two dielectric layers prevents the reformation of a dissolved filament by blocking the oxygen vacancies, which brings a first advantage in terms of stability of the stack, and thus in terms of retention capability for a memory employing this stack as a memory element.

A second advantage is that the diffusion barrier widens the gap in resistance between LRS and HRS, which makes it is easier to distinguish between the LRS and HRS of the memory.

According to further non limitative features of the first aspect of the invention, either taken alone or in any technically feasible combination:
the first electrode can be an inert electrode and the second electrode can be an active electrode, able to scavenge oxygen ions from the dielectric layer;
the second dielectric layer can have a migration energy that is higher than a migration energy of the first dielectric layer;
the second dielectric layer can have a thickness comprised between 20% and 60% of the combined thicknesses of the first dielectric later, the diffusion barrier and the second dielectric layer;
the first dielectric layer can be formed from hafnium oxide or tantalum pentoxide;
the first dielectric layer can have a thickness comprised between 1 and 4 nm, preferably between 2 and 3 nm;
the second dielectric layer can be formed from zirconium oxide;
the second dielectric layer can have a thickness comprised between 1 and 4 nm, preferably between 2 and 3 nm;
the diffusion barrier can be formed from aluminum oxide;
the diffusion barrier can be formed from C, SiO2, Si, TaSiN, TaCN or TiSiN;
the diffusion barrier can have a thickness comprised between 0.2 and 2 nm, preferably between 0.4 and 1 nm;
at least the first dielectric layer and the second dielectric layer can be doped with a trivalent element at an atomic concentration comprised between 1% and 15%;
the trivalent element can be chosen among Ti, Al and La;
at least the first dielectric layer and the second dielectric layer can each be doped with silicon at an atomic concentration comprised between 1% and 15%, preferably between 2% and 6%; and
the dielectric layer can further comprise a second diffusion barrier layer interposed between the second dielectric layer and the second electrode.

The invention extends to a memory device comprising an array of bit cells each comprising the stack according the first aspect of the invention as a variable resistor and to an embedded system comprising the memory device in communication with a microprocessor.

### BRIEF DESCRIPTION OF DRAWINGS

Many other features and advantages of the present invention will become apparent from reading the following detailed description, when considered in conjunction with the accompanying drawings, in which:

FIG. 1 illustrates the principle of operation of an OxRAM;

FIG. 2 illustrates the repartition of the resistivities of bit cells of a resistive memory;

FIG. 3 illustrates a mechanism leading to lack of retention of the high resistive state of an OxRAM memory element;

FIG. 4 illustrate a memory element solving the issue illustrated by FIG. 3;

FIG. 5 shows graphs comparing retention performances of the memory elements illustrated by FIGS. 3 and 4;

FIG. 6 represents a diagram of a fabrication process for the memory element illustrated by FIG. 4;

FIG. 7 illustrates variants of the memory element illustrated by FIG. 4;

FIG. 8 illustrates an OxRAM memory array incorporating the memory element illustrated by FIG. 4; and

FIG. 9 illustrates an embedded system incorporating the OxRAM memory array illustrated by FIG. 8.

### DETAILED DESCRIPTION OF A FIRST EMBODIMENT OF THE INVENTION

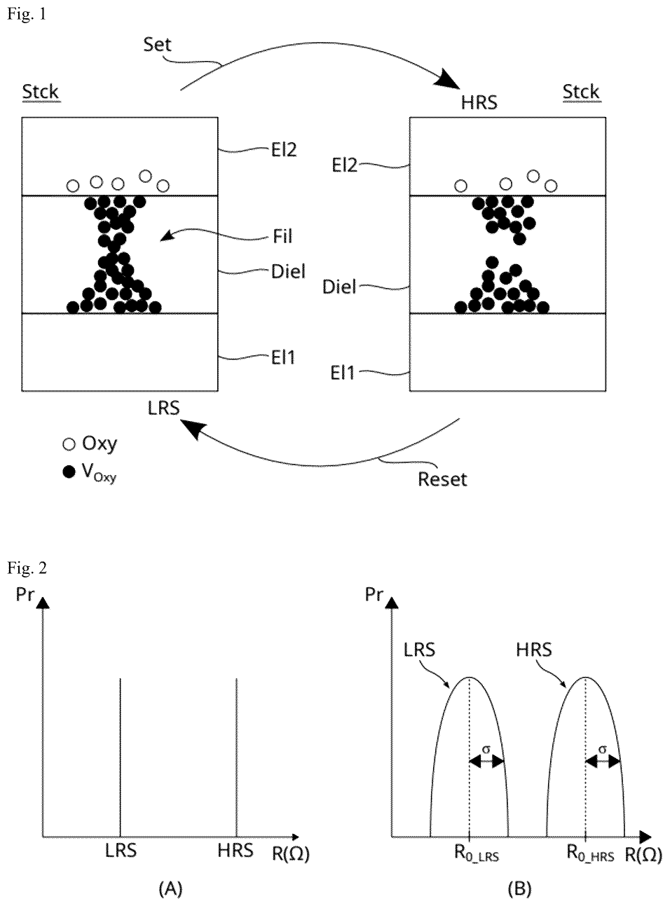

An embodiment of the invention will be described hereunder, with the help of FIGS. 1 to 9.

FIG. 3 illustrates a stack Stck forming a memory element of an OxRAM memory. The stack comprises a first, inert, electrode El1 and a second, active, electrode El2 able to scavenge oxygen ions, with a dielectric layer Diel interposed there between. The dielectric layer Diel comprises a first dielectric layer Diel1 formed from a first transition metal oxide situated on the side of the first electrode and a second dielectric layer Diel2 formed from a second transition metal oxide that is situated on the side of the second electrode and that has a higher migration energy than the first metal oxide. The first electrode El1 can be an inert electrode made of titanium nitride TiN, the first layer Diel1 and the second layer Diel2 of the dielectric layer Diel can be made of a dielectric hafnium oxide HfO₂ and a dielectric zirconium oxide ZrO₂, respectively, the second electrode El2 can be made of an oxygen scavenging layer made of titanium Ti.

OxRAM memories cells employing such a structure have been studied by the applicant of the present application. It appeared that they exhibit an insufficient retention of, notably, the high resistive state HRS. The HRS state is obtained by dissolving a filament Fil made of oxygen vacancies V_{Oxy}. It has then been hypothesized that a filament dissolved after a reset operation may reform itself due to mobility of the oxygen vacancies within the HfO₂ layer, the ZrO₂ layer immobilizing them sufficiently due to its high migration energy. This situation is illustrated by FIG. 3, arrows symbolizing the migration of the oxygen vacancies V_{Oxy} tending to reform a dissolved filament DisFil in the second dielectric layer Diel2.

As a countermeasure, the applicant proposed to interpose a diffusion barrier interposed between the two dielectric layers Diel1 and Diel2, with the intent of preventing the oxygen vacancies to diffuse and reform the dissolved filament, and thus enhancing the retention ability of the memory element.

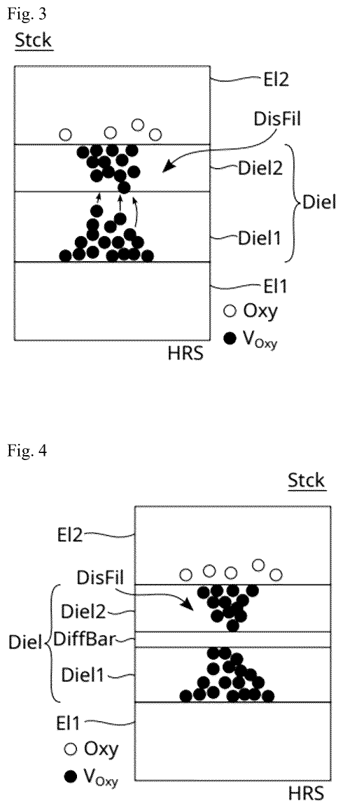

FIG. 4 illustrates the general structure of an OxRAM stack according to the invention, which differs from the structure illustrated by FIG. 3 merely by the presence of the diffusion barrier DiffBar interposed between the two dielectric layers Diel1 and Diel2. Advantageously, the diffusion barrier prevents the reformation of the dissolved filament by blocking the oxygen vacancies. The efficacy of this structure has been confirmed by comparing the retention of the structures illustrated by FIGS. 3 and 4, respectively, with a diffusion barrier made of aluminum oxide.

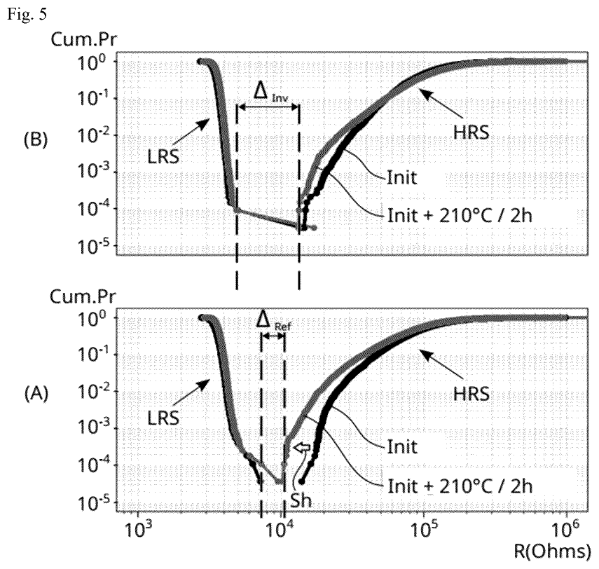

FIG. 5 shows at (A) and (B) two graphs illustrating measurement results for OxRAM memories based on memory cells employing structures identical to each other, except for the presence of a diffusion barrier DiffBar formed from aluminum oxide Al₂O₃ between the HfO₂ and ZrO₂ layers for the test graph at (B) while this diffusion barrier layer is absent for the reference graph at (A).

The graphs represent the distribution of the memory cells as a function of their respective resistances for the LRS states and HRS states. The graphs have a common X-axis expressing the resistance R of a memory cell in ohms and Y-axes expressing the cumulative probability Cum.Pr of having a given resistance, arranged to easily visualize the proximity of the HRS and the LRS states, i.e. the proportions of LRS and HRS states that are close to each other and may lead to loss of retention and errors during read operations.

The graphs at (A) and (B) show each two sets of results. The first sets indicated as Init corresponds to the resistance of memory cells just after set or reset operations writing their LRS and HRS states. A second set indicated as Init+210° C./2 h shows the resistance of the same memory cells after the set or reset operations and an additional heat treatment at 210° C. during 2 hours. The heat treatment tests the ability of the memory cells to retain information, i.e. the LRS and HRS states written therein.

As visible in the reference graph at (A), memory cells based on an HfO₂/ZrO₂ structure, without Al₂O₃ diffusion barrier, exhibit an important shift Sh (as indicated by an arrow) of their HRS states towards the LRS states after the thermal treatment, reducing drastically the gap in resistance Δ_{Ref} separating the HRS and LRS states for cumulative probabilities of 10⁻⁴.

In contrast, as visible in the graph at (B), memory cells based on an HfO₂/Al₂O₃/ZrO₂ structure, including an Al₂O₃ diffusion barrier, exhibit a reduced shift of the HRS states towards the LRS states, limiting drastically the reduction of the gap in resistance Δ_{Inv} separating the HRS and LRS states for cumulative probabilities of 10⁻⁴. It is also of note that the gap in resistance is initially (prior to the thermal treatment) wider.

The introduction of the diffusion barrier DiffBar between the dielectric layers Diel1 and Diel2 appears advantageous on two aspects. A first aspect is that the HRS states appear more stable, which is positive as to the retention ability of OxRAM memories. A second aspect is that it is easier to distinguish between the LRS and HRS states of the memory.

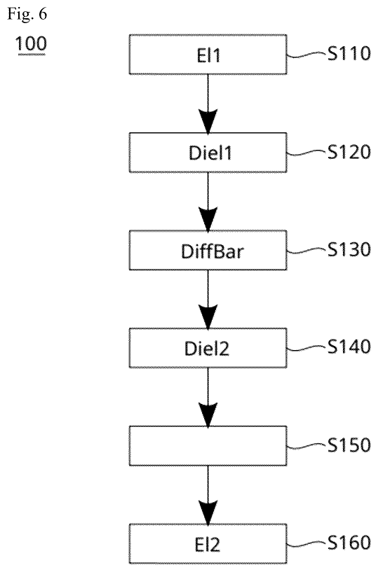

Additional characteristics of the stack Stck according to the invention and illustrated by FIG. 4 are explained below, with the help of FIG. 6 that illustrates a process 100 of fabrication of the stack Stck comprising successive steps S110 to S160.

In this description, it has to be understood than when a layer is formed from a given material, this layer comprises this material at an atomic concentration of more than 50%.

At the first step S110, the first electrode El1 is, for example, formed over a base substrate (not represented on the figures) by cathodic sputtering in a vacuum deposition chamber to be preferably 5 nm thick or more. Preferably, the first electrode is chemically inert in the stack and does not react with the oxygen ions or the oxygen vacancies mobile in the dielectric layers. In the present embodiment, the first electrode El1 can be formed from titanium nitride TiN by reactive sputtering. Alternatively, the first electrode can be formed by chemical vapor deposition.

At the step S120, the first dielectric layer Diel1 is formed on the first electrode El1.

In the present embodiment, the dielectric layer Diel1 is a dielectric hafnium oxide layer such as HfO₂, with a thickness comprised between 1 and 4 nm, preferably between 2 and 3 nm, typically 2 nm. Alternatively, the dielectric layer Diel1 may be, for example, a tantalum pentoxide layer. A layer Diel1 too thin leads to a read margin too small, while a layer Diel1 too thick can degrade the switching between LRS and HRS states and generate resistance tails.

At the step S130, the diffusion barrier layer is formed on the first dielectric layer Diel1.

In the present embodiment, the diffusion barrier layer DiffBar is a dielectric aluminum oxide layer such as Al₂O₃, with a thickness comprised between 0.2 and 2 nm, preferably between 0.4 and 1 nm. Appropriate thickness is chosen so that the layer is thin enough so as to not introduce a too high electrical resistance to the stack, and thick enough so as to fulfill sufficiently its intended function. The active material layer can be deposited by cathodic sputtering, by physical vapor deposition (PVD), or by ion beam deposition (IBD), for example.

The invention is not limited to aluminum oxide, as other materials that can fulfill the same function of blocking the oxygen vacancies V_{Oxy} may be employed instead, such as C, SiO2, Si, TaSiN, TaCN or TiSiN, for example. In any event, the material chosen to form the layer DiffBar has a barrier property with regard to oxygen vacancies that is higher than the barrier properties of the layers Diel1 and Diel2.

At the step S140, the second dielectric layer Diel2 is formed on the diffusion barrier layer DiffBar.

In the present embodiment, the dielectric layer Diel2 is a dielectric zirconium oxide layer such as ZrO₂, with a thickness comprised between 1 and 4 nm, preferably between 2 and 3 nm. The dielectric layer Diel2 preferably has a thickness comprised between 20% and 60% of the combined thicknesses of the layers Diel1, DiffBar and Diel2. A layer Diel2 too thick can degrade the switching between LRS and HRS states and generate resistance tails. If the layer Diel2 is too thin, the structure combining Diel2 and DiffBar does not bring significant retention gain to the ReRAM.

In this embodiment, the layers Diel1, DiffBar and Diel2 are preferably deposited in such a way that they present substantially constant thicknesses at all points. In this description, “substantially constant thickness” refers to a thickness that does not vary by more than 20%, preferably by more than 10%, and even more preferably by more than 5%.

As for the formation method, in this embodiment, the layers Diel1, DiffBar and Diel2 are deposited by an atomic layer deposition (ALD) method. Alternatively, these layers can be deposited by cathodic sputtering, by physical vapor deposition (PVD), or by ion beam deposition (IBD), independently, for example.

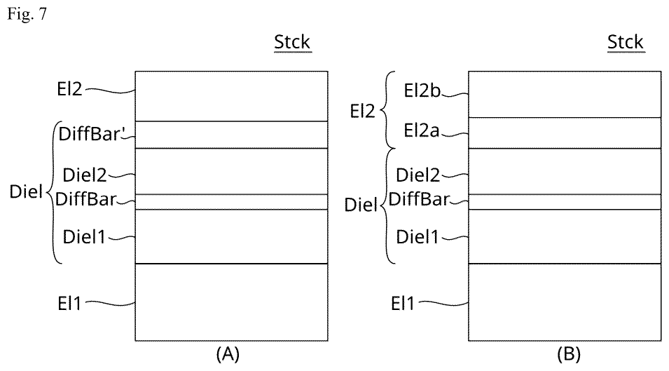

A variation to the structure of FIG. 4 is illustrated by FIG. 7(A). This structure is the same as that of FIG. 4, except that the dielectric layer Diel comprises an additional diffusion barrier DiffBar′ interposed between the second dielectric layer Diel2 and the second electrode El2. The layer DiffBar′ is formed from a semiconductor, preferably Si, or a semiconductor oxide or a metal oxide, preferably silicon oxide SiO2 or aluminum oxide Al₂O₃. The layer DiffBar′ has for function to provide an additional barrier between the electrode El2 and the other layers forming Diel. Its function is to help setting a balance in the movement of the oxygen ions to allow reset operation while enhancing retention of the LRS states.

At the step S150, as a first alternative, the layers forming the dielectric layer Diel are submitted to doping of trivalent element by ion implantation at least of the first dielectric layer Diel1 and the second dielectric layer Diel2, so as to control the migration energy for oxygen and oxygen vacancies. The trivalent dopant may be Ti, Al, La, or the like. In a second alternative, in order to create defects in the dielectric layers, silicon, argon or nitrogen may be implanted therein. These defects have for purpose to favor oxygen vacancies motion and facilitate switching between LRS and HRS states. A too high concentration of silicon can degrade resistance margin.

For both alternatives, direct implantation may take place by implanting the selected dopant element at, for example, a doping energy comprised between 1.5 keV and 3.5 keV, typically 3 keV, and at dose comprised between 1·10¹⁵ and 5·10¹⁵ atoms/cm², preferably between 2·10¹⁵ and 3·10¹⁵ atoms/cm², typically 2·10¹⁵ atoms/cm². The dopant element represents between 1% and 15%, preferably between 2% and 7%, of the atoms present in the layers forming the layer Diel. A too high concentration of defects can degrade LRS states retention by the ReRAM.

Other processes may also be used without departing from the scope of the disclosed embodiments. For example, doping can be performed during the formation of the layers.

At the step S160, the second electrode El2 is formed on the second dielectric layer Diel2, for example, formed by cathodic sputtering in a vacuum deposition chamber to be about 5 nm thick. The second electrode can be an oxygen scavenging layer, that participate to the formation and the retention of a conductive filament made of oxygen vacancies during a set operation, by capturing and neutralizing oxygen species, preventing them from recombining with the oxygen vacancies of the filament and thus from dissolving the filament. In the present embodiment, the second electrode El2 is preferably formed from titanium Ti, but could also be formed from another transition metal, and could for example be formed from TaN, Hf or Ta. As an alternative to the cathodic sputtering, the first electrode can be formed by chemical vapor deposition or by ion beam deposition.

A variant to the second electrode El2 of FIG. 4 is illustrated by FIG. 7(B). This structure Stck is the same as that of FIG. 4, except that the second electrode El2 has a composite structure, comprising a first electrode layer El2a on the side of the second dielectric layer Diel2 and a second electrode layer El2b on the opposite side. The first electrode layer El2a is preferably an oxygen scavenging layer in direct contact with the second dielectric layer and can be formed from Ti, Hf, or Ta, to have a thickness comprised between 3 nm and 20 nm for example. The second electrode layer El2b is formed from a conductive material comprising a transition metal, and has for function to prevent a complete oxidation of the first electrode layer El2a and to allow to take electrical contact with the electrode El2. El2b can be formed from TiN, TaN or W, for example.

After completion of the stack, and prior to its regular use as a bit element of an OxRAM memory, the stack is submitted to a “forming” initialization step that consists in forming an initial filament. The voltage used to form this initial filament is higher than the set voltage Vset. The initialization stage occurs only once in the lifetime of each bit cell of the memory.

In this description, two directly adjacent layers are in direct physical contact with each other, except otherwise specified.

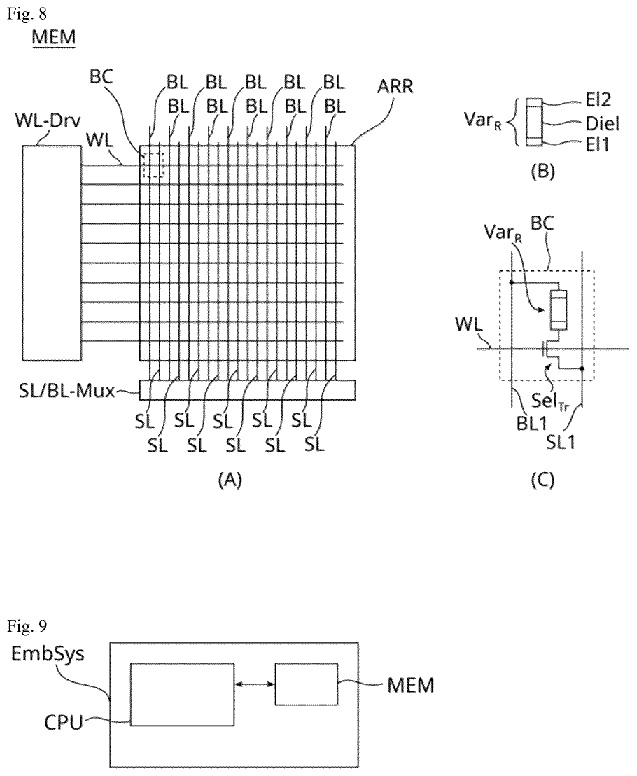

The stack Stck described above can form the active elements of an OxRAM memory MEM. The set, reset and read operations can be applied to bit cells integrated in an array ARR, each of the bit cells comprising a stack Stck. FIG. 8 illustrates a basic, conventional structure of a resistive memory MEM. Such a memory is described for example in the U.S. Pat. No. 11,735,260B2.

Typically, as illustrated by FIG. 8(C), each bit cell BC of the array ARR comprises (i) one stack Stck that forms a variable resistor Var_{R} (see FIG. 8(B)) and fulfill the function of a memory bit element for each bit cell, and (ii) one selection transistor Sel_{Tr} having a source and a drain connected in series with the variable resistor.

An array ARR of bit cells typically comprises columns and rows of bit cells, as illustrated by FIG. 1(A). Each column comprises (i) a bit line BL connected to a source and a drain of the transistor Sel_{Tr} through the variable resistor Var_{R} for each of the bit cells of the column and (ii) a source line SL connected to the bit line BL through the source and the drain of the transistor Sel_{Tr} and the variable resistor Var_{R}. Each row of bit cells comprises a word line WL connected to the gate of the selection transistor Sel_{Tr} for each of the bit cells of the row. The bit lines BL and the source lines SL are each connected to and controlled through a column multiplexer circuit SL/BL-Mux. The word lines WL are each connected to and controlled by a row driver circuit WL-Drv.

FIG. 9 illustrates an embedded system EmbSys integrating a OxRAM in communication with a microprocessor CPU. Such a system can be a portable semiconductor device configured to treat numerical data. Generally speaking, any embedded device conventionally employing a flash memory may employ a resistive memory instead. The OxRAM can benefit from the enhanced retention capability of the stack Stck described above, and can make it especially suited for high temperature applications such as transport applications.

Other variations to the disclosed embodiments can be understood and effected by those skilled in the art in practicing the claimed invention, from a study of the drawings, the disclosure, and the appended claims.

What is claimed is:

1. A resistive stack for a resistive random-access memory cell, the resistive stack comprising:
a first electrode;
a second electrode;
a dielectric layer interposed between the first electrode and the second electrode, the dielectric layer comprising:
a first dielectric layer formed from a first transition metal oxide formed from a first transition metal;
a second dielectric layer formed from a second transition metal oxide formed from a second transition metal, the first transition metal being different from the second transition metal; and
a diffusion barrier layer interposed between the first dielectric layer and the second dielectric layer, and formed from a material having a barrier property with regard to oxygen vacancies, that is higher than barrier properties with regard to oxygen vacancies of the first transition metal oxide and the second transition metal oxide, the diffusion barrier layer being formed from aluminum oxide, SiO2 or Si.

2. The resistive stack according to claim 1, wherein the first electrode is an inert electrode and the second electrode is an active electrode able to scavenge oxygen ions from the dielectric layer.

3. The resistive stack according to claim 1, wherein the second dielectric layer has a migration energy that is higher than a migration energy of the first dielectric layer.

4. The resistive stack according to claim 1, wherein the second dielectric layer has a thickness comprised between 20% and 60% of the combined thicknesses of the first dielectric layer, the diffusion barrier and the second dielectric layer.

5. The resistive stack according to claim 1, wherein the first dielectric layer is formed from hafnium oxide or from tantalum pentoxide.

6. The resistive stack according to claim 5, wherein the first dielectric layer has a thickness comprised between 1 and 4 nm.

7. The resistive stack according to claim 5, wherein the first dielectric layer has a thickness comprised between 2 and 3 nm.

8. The resistive stack according to claim 1, wherein the second dielectric layer is formed from zirconium oxide.

9. The resistive stack according to claim 8, wherein the second dielectric layer has a thickness comprised between 1 and 4 nm.

10. The resistive stack according to claim 8, wherein the second dielectric layer has a thickness comprised between 2 and 3 nm.

11. The resistive stack according to claim 1, wherein the diffusion barrier is formed from aluminum oxide.

12. The resistive stack according to claim 1, wherein the diffusion barrier has a thickness comprised between 0.2 and 2 nm.

13. The resistive stack according to claim 1, wherein the diffusion barrier has a thickness comprised between 0.4 and 1 nm.

14. The resistive stack according to claim 1, wherein at least the first dielectric layer and the second dielectric layer are doped with a trivalent element at an atomic concentration comprised between 1% and 15%.

15. The resistive stack according to claim 14, wherein the trivalent element is chosen among Ti, Al and La.

16. The resistive stack according to claim 1, wherein at least the first dielectric layer and the second dielectric layer are each doped with silicon at an atomic concentration comprised between 1% and 15%.

17. The resistive stack according to claim 1, wherein at least the first dielectric layer and the second dielectric layer are each doped with silicon at an atomic concentration comprised between 2% and 6%.

18. The resistive stack according to claim 1, wherein the dielectric layer further comprises a second diffusion barrier layer interposed between the second dielectric layer and the second electrode.

19. A memory device comprising an array of bit cells each comprising the stack according to claim 1 as a variable resistor.

20. An embedded system comprising the memory device according to claim 19 in communication with a microprocessor.
